(19) United States
(12) Patent Application Publication
(10) Pub. No.: US 2010/0030501 A1
(43) Pub. Date: Feb. 4, 2010

(54) General-Purpose AC Impedance Metering and Recording Device

(76) Inventor: Tony-Sheng LIN, Taipei (TW)

Correspondence Address: HOGAN & HARTSON L.L.P., 1999 AVENUE OF THE STARS, SUITE 1400, LOS ANGELES, CA, 90067, US

(21) Appl. No.: 12/533,580

(22) Filed: Jul. 31, 2009

(30) Foreign Application Priority Data
Aug. 1, 2008 (TW) 097213745

(51) Int. Cl. G06F 19/00; G06F 12/00; G06F 3/048; G01R 27/00

(52) U.S. Cl. 702/65; 711/115; 715/771; 702/187

(57) ABSTRACT

The present invention relates to a general-purpose security-enhanced recording device with unlimited memory to store AC impedances being measured. The device adopts a processor unit to perform a systematic combined computation control and employs a portable mass data storage technique to provide users unlimited storage capacity for automatic storage space of measurement data. Integrated with a built-in multiplexing control unit, the device effectively expands the number of the measurable input sources. Integrated with a design of virtual console based on PC software, the device effectively enhances system security. The device can be used indoors and outdoors, and operated as a standalone unit or one in a LAN environment.

### FIELD OF THE INVENTION

The present invention relates to an AC impedance measurement device, and more particularly to a general-purpose security-enhanced recording device with unlimited memory to store the AC impedances being measured.

### BACKGROUND OF THE INVENTION

In the application field of electronic measurement gauges, the measurement of resistance is normally completed by an ohmmeter. Most of ohmmeters measure DC resistance value, while the measurement of AC resistance turns out to be impedance. The magnitude thereof includes DC resistance and capacitance and inductance taken place only in an AC environment. During regular measurement of impedance, incorrect result always incurs as a result of noise interference. As there are many AC signals with different magnitudes existing in the living environment, the measurement of impedance is increasingly important in lots of practical applications such as instruments having sensitive and accurate electronic circuits, grounding system of factories or automated electrical and mechanical production systems, whose partial or overall AC impedance measurement often becomes a must.

The origins of impedance in a real environment could be many and are often correlated one another. Hence, a synchronous and simultaneous measurement is frequently required. A measurement device providing the input capability of multiple choices and a flexible space corresponding to the required storage of input should bring into play. Data stored after an impedance measurement should be automatically recorded. Manual recording should be avoided to eliminate incorrect or false content. If a measurement device intensively measures multiple inputs, the data amount could be sizable. Consequently, a design of unlimited storage capacity is an indispensable choice applied in a practical application occasion.

Regularly, conventional measurement instruments are all equipped with a hardware input device serving as an input tool inputting basic control parameters. However, due to weak management and uncontrollable access of personnel to the operating environment, the resulting security of a measurement gauge is very vulnerable. As such, to be security-enhanced has long become a wishful feature that users expect from an impedance measuring device. Enhancing the management of a conventional hardware input device is a pretty common administrative method with little effect. Instead, more effect can be gained by the breakthrough with technical means. Directly replacing the hardware input device with a virtual console on a basis of software could be one technique achieving higher security-enhanced effect.

### SUMMARY OF THE INVENTION

The main objective of the present invention is to provide a general-purpose security-enhanced recording device with unlimited memory to store the AC impedances being measured for solving the issue of the conventional technique. The device adopts a processor unit to perform a systematic combined computation control and employs a portable mass data storage technique to provide users unlimited storage capacity for automatic storage space of measurement data. Integrated with a built-in multiplexing control unit, the device effectively expands the number of the measurable input sources. Integrated with a design of virtual console based on PC software, the device effectively enhanced system security. The device can be used indoors and outdoors, and operated as a standalone unit or networked in an LAN environment.

To achieve the foregoing objective, a general-purpose security-enhanced recording device with unlimited memory to store the AC impedances being measured comprises: an input selection unit, a constant signal source, an adaptive selection block 104, a signal conversion and formation unit, an analog/digital (A/D) converter, a data formatting and integration unit, a processor unit, a memory storage management unit, a display unit, a primary communication unit, a multiplexing input control unit, a secondary communication unit, a LAN/network interface unit, an AC power supply unit and a DC power supply unit.

The input selection unit is connected with and controlled by the processor unit, has multiple pairs of input lines. In terms of the system, each pair of input lines forms an input having impedance load. The constant signal source is used to form a constant current source circuit. The adaptive selection block selects a circuit frequency to alter a current frequency outputted from the constant signal source. The signal conversion and formation unit converts impedance values in the form of signal from the input selection unit into voltage signals. An analog-digital conversion unit converts the voltage signals of analog impedance values outputted by the signal conversion and formation unit into digital data to facilitate posterior digital signal processing. A data formatting and integration unit converts bus data into serial data. A processor unit receives the formatted signals from the data formatting and integration unit to perform a systematic combined computation control. A multiplexing input control unit, one end of the multiplexing input control unit is connected to the processor unit, the other end thereof is connected to an externally connected multiplexer, the multiplexing input control unit provides a port coordinating handshaking commands and data of the externally input multiplexer and the device, the output of the externally connected multiplexer is connected to any input of the device, so that the device orderly measures impedances of multiple objects to be measured. The processor unit further controls the multiplexing input control unit to select an object to be measured and informs the input selection unit of a current object to be measured. The memory storage management unit manages a cache memory and a plurality of portable mass memory devices so that data stored therein are able to carried to other information device for processing and users swap the portable mass memory device for a new empty memory device when the portable mass memory device is fully occupied; wherein the memory storage management unit performs a successive management of all measurement data stored in the plural portable mass memory devices to continuously store the measurement data in all the empty mass memory devices.

These and other features and advantages of some embodiments of the invention are detailed below with reference to the following drawings,

### BRIEF DESCRIPTION OF THE DRAWINGS

FIG. 1 is a block diagram illustrating a system of the present invention; and

FIG. 2 is a flow diagram illustrating operation of the present invention.

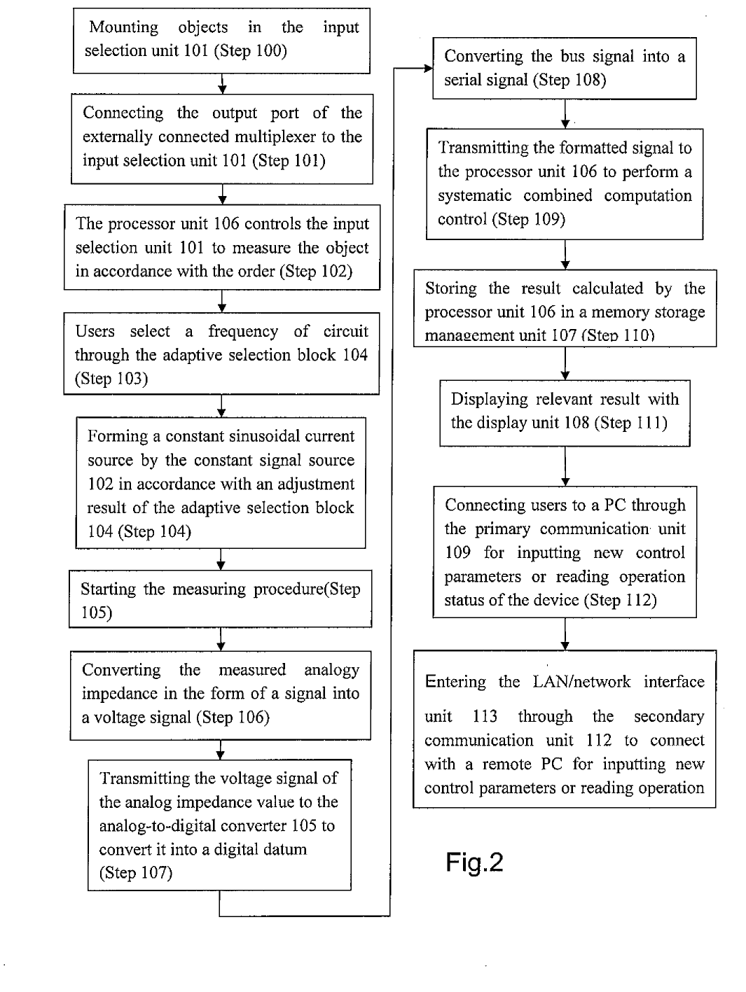

### DETAILED DESCRIPTION OF THE PREFERRED EMBODIMENT

The composition, efficacy and advantages of the present invention are depicted in details with a preferred embodiment in collaboration with drawings.

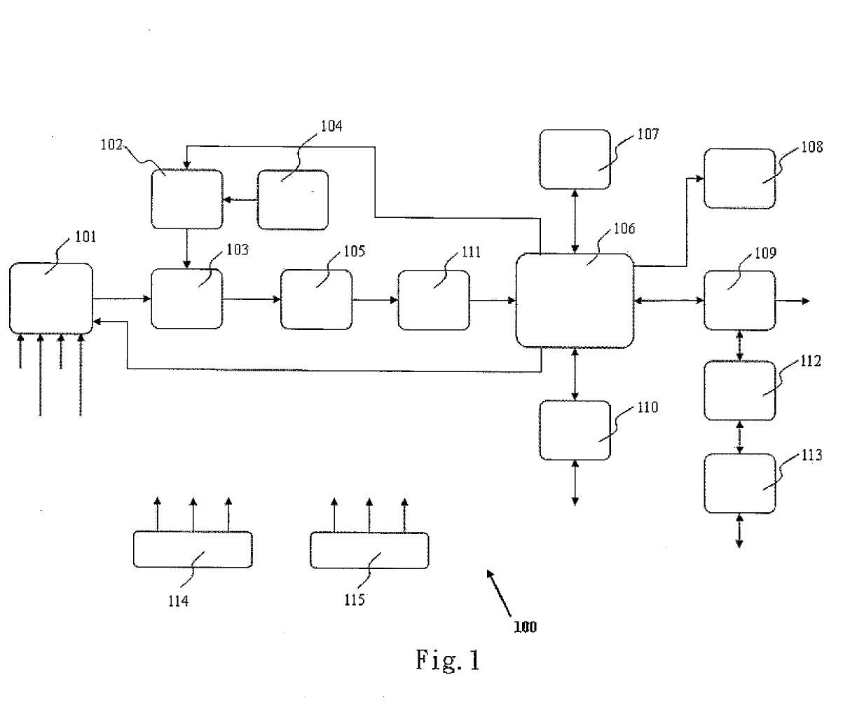

With reference to FIG. 1, a general-purpose security-enhanced recording device for unlimited memory to store the AC impedances being measured includes an input selection unit 101, a constant signal source 102, an adaptive selection block 104, a signal conversion and formation unit 103, an analog/digital (AND) converter 105, a data formatting and integration unit 111, a processor unit 106, a memory storage management unit 107, a display unit 108, a primary communication unit 109, a multiplexing input control unit 110, a secondary communication unit 112, a LAN/network interface unit 113, an AC power supply unit 114 and a DC power supply unit 115.

The input selection unit 101 has n input lines which are grouped into n/2 pairs with two lines in each pair. Each pair of lines to the system forms an input of impedance load. Users can select any pair out of the n/2 pairs of lines to connect with the output and a reference signal line of an N-to-1 multiplexer. Input can be selected in turn by scanning and controlling through a processing unit or configuring to be manual selection.

The constant signal source 102 is a constant current source circuit forming a sinusoidal wave and outputting a current with an adequate frequency in accordance with an impedance measurement range. Selecting the impedance measurement range is automatically determined by a processor unit of the present invention and the range should match with that of the object to be measured.

The adaptive selection block 104 selects a frequency of a circuit to alter the frequency of the current outputted by the constant signal source 102. Users can modulate an optimal circuit frequency (1K-2K Hz) to ensure a possibly lowest noise interference under different working environments.

The signal conversion and formation unit 103 functions to convert an impedance value in the form of a signal from the input selection unit 101 into a voltage signal. The input impedance load resulting from the input selection unit 101 is taken into account for calculation by a measurement circuit. The signal conversion and formation unit 103 also filters and amplifies the voltage signal.

The analog-to-digital converter 105 converts the voltage signal of an analog impedance value outputted by the signal conversion and formation unit 103 into a digital signal to facilitate posterior digital signal processing.

The data formatting and integration unit 111 temporarily stores data and formats the data. Bus signals are converted into serial signals to facilitate the subsequent processing of the processing unit. The analog-to-digital converter 105 and the data formatting and integration unit 111 can be integrally formed as one unit.

The processor unit 106 receives the formatted data from the data formatting and integration unit 111 to perform a systematic combined computation control, manage unlimited storage memory and support virtual console and communication instructions to port of multiplexer. The processor unit 106 may be an application-specific central processing block that receives the formatted data from the data formatting and integration unit 111 and performs various different processing to the data, namely operation control of entire system, memory management of data storage, support of control commands to remote console and control over external multiplexer.

The memory storage management unit 107 manages cache memory and portable mass memory device (e.g. MD device in a personal computer) for all different types of memories such as swappable memory, so that data can be carried and processed in other information devices. While a portable mass memory device is fully occupied, the memory storage management unit 107 of the present invention allows users to swap for a new empty memory device. The memory storage management unit 107 performs successive management to all measured data stored in a plurality of portable mass memory devices so as to attain continuous storage function in various different empty memory devices.

The display unit 108 is connected to the processor unit 106 to display data relevant to the processor unit 106 or data and results relevant to user's input. The display unit 108 may be an LCD/LED panel displaying status of system operation and on-site measured data or stored measurement result.

The primary communication unit 109 is connected with the processor unit 106. The primary communication unit 109 provides an interface to a personal computer (PC) and uses software in user's PC serving as an auxiliary input console of the system to input system control parameters and generate reports. Given such approach, the device provides no on-site hardware input device to prevent unauthorized personnel from inappropriately accessing to the device, further ensuring security and controllability of the device.

The multiplexing input control unit 110 has one end connected to the processor unit 106 and the other end connected to an externally connected multiplexer. The multiplexing input control unit 110 allows an input multiplexer to be externally connected to serve as a port for coordinating the handshaking commands of the device and data. Besides, the output of the externally connected multiplexer is connected to any input of the device. The multiplexing input control unit 110 allows the device of the present invention to sequentially measure impedance of multiple objects to be measured. The processor unit 106 controls the multiplexing input control unit 110 to select one object to be measured and inform the input selection unit 101 what the object been currently measured is, so that the input selection unit 101 incorporates the multiplexing input control unit 110 to measure the impedance value of the selected object to be measured. After the measurement of the impedance value of the object to be measured is completed, the measurement of next object to be measured is immediately conducted. Such sequences are repeated until the impedances of all objects to be measured are measured. Based on the settings of the control parameters in the processor unit 106, the measured results, either normal or abnormal, are sequentially recorded in a memory and the indication given by the processor unit 106 is also recorded. Consequently, users can simultaneously measure the impedance values of multiple objects to be measured and record the results.

The secondary communication unit 112 is connected with the primary communication unit 109 so that the secondary communication unit 112 provides a circuit interface for the condition able to communicate in a LAN environment.

The LAN/network interface unit 113 is connected with the secondary communication unit 112 to provide an interface to connect to a remote PC. Software executed by users in a PC serves as a remote input console of the device for inputting control parameters of the device and generating reports. Given such approach, the device provides no on-site hardware input device to prevent the system from being interfered by inappropriately authorized on-site personnel and further enhance overall security and control of the system. The LAN/network interface unit 113 is adopted to connect with a remote console. When the LAN/network interface unit 113 is a PC, it acts as a user-oriented console to serve as a configuration and report device, providing remote input of configuration and enhanced security control over the device.

The AC power supply unit 114 provides the power for indoor use of the entire device. The DC power supply unit 115 provides the power for outdoor use of the entire device.

Operation of the present invention is described as follows: mounting m objects to be measured in the input selection unit 101; respectively connecting two wires for each object to be measured and totally 2 m input lines to the input point and output points of the m object to be measured; connecting each object to be measured and the corresponding input line to form a conducting loop (Step 100); selecting any one of the m objects to be measured and connecting it to a reference point of a common loop of a data output port of the externally connected k-input multiplexer and the multiplexer; reporting an input position of the input selection unit 101 connected to the processor unit 106 to facilitate correct handshaking and intercommunication with the multiplexing input control unit 110; connecting the multiplexing input control unit 110 to the processor unit 106 (Step 101); sequencing the operation order of the objects to be measured, totally (m+k−1) objects, with the processor unit 106 to enable the input selection unit 101 to measure the objects to be measured in accordance with the order (Step 102); entering a measuring process for users to select a frequency of circuit through the adaptive selection block 104 (Step 103); obtaining a reliable measurement result of minimum noise interference under different working environment by altering the current frequency outputted from the constant signal source 102; forming a constant sinusoidal current source by the constant signal source 102 in accordance with an adjustment result of the adaptive selection block 104 and selecting a proper impedance measurement range under the control of the processor unit 106 (Step 104); instructing the input selection unit 101 with the processor unit 106 to sequentially measure the selected positions (Step 105); measuring the impedance of the selected object to be measured; measuring and processing the loop load provided by the selected object to be measured in the signal conversion and formation unit 103 to convert the impedance in the form of a signal into a voltage signal (Step 106); transmitting the voltage signal of the analog impedance value outputted by the signal conversion and formation unit 103 to the analog-to-digital converter 105 to convert it into a digital datum facilitating a posterior digital signal processing (Step 107); transmitting the digital signal outputted by the analog-to-digital converter 105 to the data formatting and integration unit 111 to format the data of the digital signal and convert the bus signal into a serial signal for subsequent processing of the processor unit 106 (Step 108); transmitting the formatted signal to the processor unit 106 to perform a systematic combined computation control (Step 109); storing the result calculated by the processor unit 106 in a memory storage management unit 107 (Step 110); providing a combination of cache memory and a portable mass memory device (e.g. MMD device in PC) or other type of memory, e.g. swappable memory, ensuring to carry data to other information device for processing and ensuring that users can swap for a new empty memory device when the portable mass memory device is fully occupied; performing successive management of all measurement data stored in a plurality of mass memory devices by the memory storage management unit to attain continuous storage in those empty memory devices; displaying relevant result with the display unit 108 (Step 111); connecting users to a PC through the primary communication unit 109 (Step 112) or entering the LAN/network interface unit 113 through the secondary communication unit 112 to connect with a remote PC for inputting new control parameters or reading operation status of the device (Step 113).

The present invention is characterized in that environmental noise interference can be avoided through an adaptive frequency signal technique so as to accurately measure the AC impedance of any electronic circuits, junction connection wires or electromechanical systems. Using portable mass data storage technique provides users unlimited storage capacity for automatic storage space of measurement data. Integrated with a built-in multiplexing control input port, the number of measurable input sources of the device can be effectively expanded. Integrated with a design of virtual console based on PC software, system security can be effectively enhanced. The present invention is good for indoor and outdoor use and serves as a standalone unit and one in a LAN network environment.

In sum, the humanized and thoughtful design of the present invention provides the practical and innovative value to the industry and the application is hereby submitted in accordance with the patent laws.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A general-purpose security-enhanced recording device with unlimited memory to store AC impedances being measured, comprising:
a processor unit for performing a systematic combined computation control;
an input selection unit connected with and controlled by the processor unit, having multiple pairs of input lines and selecting one pair of input lines at a time to be measured according to a sequence thereof; and
a memory storage management unit connected with the processor unit to manage a cache memory and a plurality of portable mass memory devices so that data stored therein are able to carried to other information devices for processing and users swap the portable mass memory device for a new empty memory device when the portable mass memory device is fully occupied;
wherein the memory storage management unit performs a successive management of all measurement data stored in the plural portable mass memory devices to continuously store the measurement data in all the empty mass memory devices.

2. The general-purpose security-enhanced recording device with unlimited memory to store AC impedances being measured as claimed in claim 1, wherein the device further comprises a multiplexing input control unit, one end of the multiplexing input control unit is connected to the processor unit, the other end thereof is connected to an externally connected multiplexer, the multiplexing input control unit provides a port coordinating handshaking commands and data of the externally input multiplexer and the device, the output of the externally connected multiplexer is connected to any input of the device, so that the device orderly measures impedances of multiple objects to be measured.

3. The general-purpose security-enhanced recording device with unlimited memory to store AC impedances being measured as claimed in claim 1, wherein the device further comprises a constant signal source for forming a constant current source circuit.

4. The general-purpose security-enhanced recording device with unlimited memory to store AC impedances being measured as claimed in claim 1, wherein the device further comprises an adaptive selection block outputting signals to the constant signal source and selecting a circuit frequency to alter a current frequency outputted from the constant signal source.

5. The general-purpose security-enhanced recording device with unlimited memory to store AC impedances being measured as claimed in claim 1, wherein the device further comprises a signal conversion and formation unit receiving signals from the constant signal source and the input selection unit and converting an impedance value in the form of a signal from the input selection unit into a voltage signal.

6. The general-purpose security-enhanced recording device with unlimited memory to store AC impedances being measured as claimed in claim 5, wherein the signal conversion and formation unit filters and amplifies the voltage signal.

7. The general-purpose security-enhanced recording device with unlimited memory to store AC impedances being measured as claimed in claim 1, wherein the device further comprises an analog-to-digital conversion and formatting unit receiving the voltage signal outputted from the signal conversion and formation unit and converting the voltage signal of the analog impedance value into a digital datum to facilitate a posterior digital signal processing, and the analog-to-digital conversion and formatting unit converts a bus signal into a serial signal.

8. The general-purpose security-enhanced recording device with unlimited memory to store AC impedances being measured as claimed in claim 1, wherein the processor unit receives the formatted signal from the analog-to-digital conversion and formatting unit to perform a systematic combined computation control, and the processor unit further controls the multiplexing input control unit to select an object to be measured and informs the input selection unit of the selected input to be measured.

9. The general-purpose security-enhanced recording device with unlimited memory to store AC impedances being measured as claimed in claim 1, wherein the device further comprises a display unit connected to the processor unit to display data relevant to the processor unit and data and results relevant to user's input.

10. The general-purpose security-enhanced recording device with unlimited memory to store AC impedances being measured as claimed in claim 9, wherein the display unit is an LCD or LED display screen.

11. The general-purpose security-enhanced recording device with unlimited memory to store AC impedances being measured as claimed in claim 1, wherein the device further comprises a primary communication unit connected with the processor unit and providing an interface to a PC.

12. The general-purpose security-enhanced recording device with unlimited memory to store AC impedances being measured as claimed in claim 11, wherein the primary communication unit provides an interface to a PC, uses software in the PC as an auxiliary input console to input system control parameters and generate reports.

13. The general-purpose security-enhanced recording device with unlimited memory to store AC impedances being measured as claimed in claim 1, wherein the device further comprises:
a secondary communication unit connected with the primary communication unit and providing a circuit interface for the condition able to communicate in a LAN environment; and
a LAN/network interface unit connected with the secondary communication unit and providing an interface to connect to a remote PC.

14. The general-purpose security-enhanced recording device with unlimited memory to store AC impedances being measured as claimed in claim 1, wherein the device further comprises an AC power supply unit to supply power of the device while operated indoors.

15. The general-purpose security-enhanced recording device with unlimited memory to store AC impedances being measured as claimed in claim 1, wherein the device further comprises a DC power supply unit to supply power of the device while operated outdoors.
